(19) United States
(12) Patent Application Publication
(10) Pub. No.: US 2011/0265848 A1
(43) Pub. Date: Nov. 3, 2011

(54) THIN FILM SOLAR CELL AND METHOD OF MANUFACTURING THE SAME

(76) Inventors: Jinhyung AHN, Seoul (KR); Sungeun Lee, Seoul (KR); Jeonghun Son, Seoul (KR)

(21) Appl. No.: 13/181,229

(22) Filed: Jul. 12, 2011

(30) Foreign Application Priority Data
Feb. 7, 2011 (KR) 10-2011-0010582

(51) Int. Cl. H01L 31/042; H01L 31/18

(52) U.S. Cl. 136/244; 438/73; 257/E31.001

(57) ABSTRACT

A thin film solar cell and a method of manufacturing the same are discussed. The method of manufacturing the thin film solar cell includes forming a plurality of cells, each cell including a first electrode on a substrate, a second electrode on the first electrode, and a photoelectric conversion unit between the first electrode and the second electrode, performing an edge deletion process to remove respective first portions of a first electrode, a second electrode, and a photoelectric conversion unit included in an outermost cell positioned at an end of the substrate among the plurality of cells, and performing an edge isolation process to remove respective second portions of the first electrode, the second electrode, and the photoelectric conversion unit included in the outermost cell.

This application claims priority to and the benefit of Korean Patent Application No. 10-2011-0010582 filed in the Korean Intellectual Property Office on Feb. 7, 2011, the entire contents of which are incorporated herein by reference.

### BACKGROUND OF THE INVENTION

1. Field of the Invention

Embodiments of the invention relate to a thin film solar cell and a method of manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A solar cell generally includes semiconductor parts that have different conductive types, such as a p-type and an n-type, and form a p-n junction, and electrodes respectively connected to the semiconductor parts of the different conductive types.

When light is incident on the solar cell, a plurality of electron-hole pairs are generated in the semiconductor parts. The electron-hole pairs are separated into electrons and holes by the photovoltaic effect. Thus, the separated electrons move to the n-type semiconductor part and the separated holes move to the p-type semiconductor part, and then the electrons and holes are collected by the electrodes electrically connected to the n-type semiconductor part and the p-type semiconductor part, respectively. The electrodes are connected to each other using electric wires to thereby obtain electric power.

### SUMMARY OF THE INVENTION

In one aspect, there is a method of manufacturing a thin film solar cell including forming a plurality of cells, each cell including a first electrode positioned on a substrate, a second electrode positioned on the first electrode, and a photoelectric conversion unit that is positioned between the first electrode and the second electrode and is configured to generate electricity from light incident on the substrate, performing an edge deletion process to remove respective first portions of a first electrode, a second electrode, and a photoelectric conversion unit included in an outermost cell positioned at an end of the substrate among the plurality of cells, and performing an edge isolation process to remove respective second portions of the first electrode, the second electrode, and the photoelectric conversion unit included in the outermost cell, wherein at least a portion of the second portions of the edge isolation process overlaps the first portions of the edge deletion process.

A width of the second portion may be less than a width of the first portions. A width of the first portions may be approximately 5 mm to 15 mm extending from the end of the substrate to the inside of the substrate. A width of the second portions may be approximately 10 μm to 100 μm.

An output power of a first laser used to remove the first portions in the edge deletion process may be greater than an output power of a second laser used to remove the second portion in the edge isolation process.

After the edge deletion process is performed, the edge isolation process may be performed. In this instance, the edge isolation process for removing the second portions may be performed on an interface between the outermost cell and a damaged region of the first electrode, the second electrode, and the photoelectric conversion unit included in the outermost cell resulting from the edge deletion process. Further, the edge isolation process for removing the second portions may be performed to remove a damaged region of the first electrode, the second electrode, and the photoelectric conversion unit included in the outermost cell resulting from the edge deletion process.

Alternatively, after the edge isolation process is performed, the edge deletion process may be performed.

In another aspect, there is a thin film solar cell including a substrate, and a plurality of cells, each cell including a first electrode positioned on the substrate, a second electrode positioned on the first electrode, and a photoelectric conversion unit that is positioned between the first electrode and the second electrode and is configured to generate electricity from light incident on the substrate, wherein no damaged region exits in a first electrode, a second electrode, and a photoelectric conversion unit included in an outermost cell positioned at an end of the substrate among the plurality of cells.

The substrate may include a first region and a second region. A dummy cell, which does not affect the generation of electricity, may not be disposed in the first region, and the plurality of cells may be disposed in the second region.

The first region may be positioned at an edge of the substrate. A width of the first region may be approximately 5 mm to 20 mm.

The photoelectric conversion unit may have at least one p-i-n structure including a p-type semiconductor layer, an intrinsic semiconductor layer, and an n-type semiconductor layer. The intrinsic semiconductor layer may contain germanium (Ge). The intrinsic semiconductor layer may contain at least one of amorphous silicon and microcrystalline silicon.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1 and 2 illustrate a thin film solar cell according to an example embodiment of the invention;

FIG. 3A illustrates an example structure of a related art solar cell in which a dummy cell is formed in a first region;

FIG. 3B illustrates a dummy cell and a damaged region as viewed from the top of the dummy cell of the related art solar cell;

FIGS. 4 to 6 specifically illustrate various cells that may be included in a thin film solar cells according to example embodiments of the invention;

FIGS. 7A to 7C relate to a method of manufacturing a thin film solar cell according to an example embodiment of the invention;

FIGS. 8A to 8C relate to another method of manufacturing a thin film solar cell according to an example embodiment of the invention;

FIG. 9 illustrates an example structure of a solar cell in which a dummy cell is not formed in a first region as viewed from the top according to an example embodiment of the invention.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

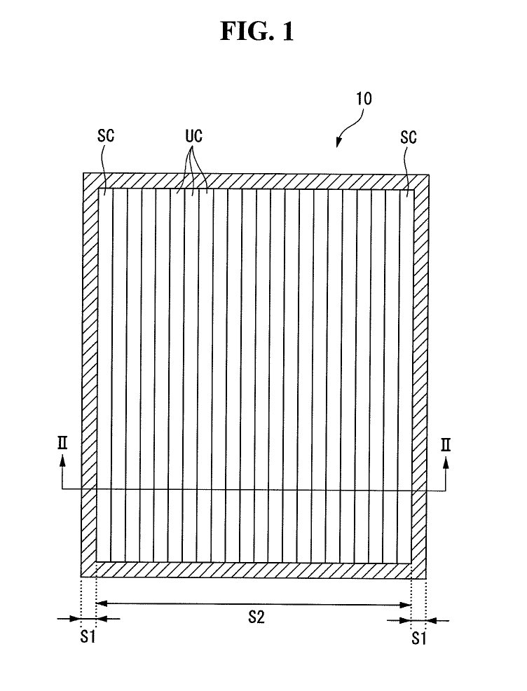

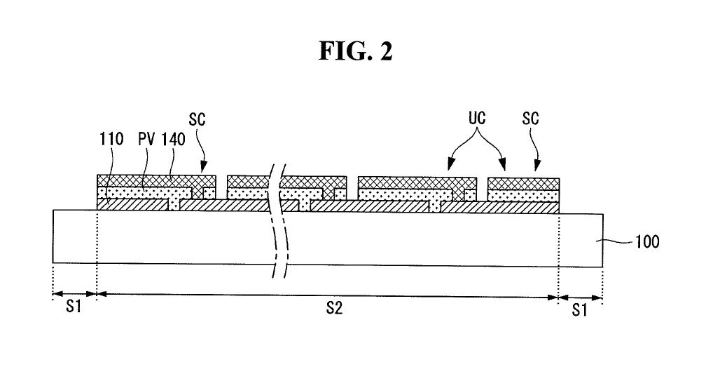

FIGS. 1 and 2 illustrate a thin film solar cell according to an example embodiment of the invention. More specifically, FIG. 1 is a plane view of a thin film solar cell, and FIG. 2 is a cross-sectional view taken along lines II-II of FIG. 1.

As shown in FIG. 1, a thin film solar cell 10 according to an example embodiment of the invention includes a substrate 100 and a plurality of effective cells UC positioned on the substrate 100. The plurality of effective cells UC substantially affect the generation of electric power. That is, the plurality of effective cells UC generate electric power in the thin film solar cell 10.

As shown in FIG. 2, each of the plurality of effective cells UC includes a first electrode 110, a photoelectric conversion unit PV, and a second electrode 140. The first electrode 110 is positioned on the substrate 100, and the second electrode 140 is positioned on the first electrode 110. The photoelectric conversion unit PV is positioned between the first electrode 110 and the second electrode 140 and converts light incident on an incident surface of the substrate 100 into electricity.

There is no a damaged region in a first electrode, a photoelectric conversion unit, and a second electrode included in an outermost cell SC positioned at the outermost side of the substrate 100 among the plurality of effective cells UC shown in FIG. 2. Hence, an electricity generation region of the thin film solar cell 10 may further increase, and photoelectric conversion efficiency of the thin film solar cell 10 may be further improved.

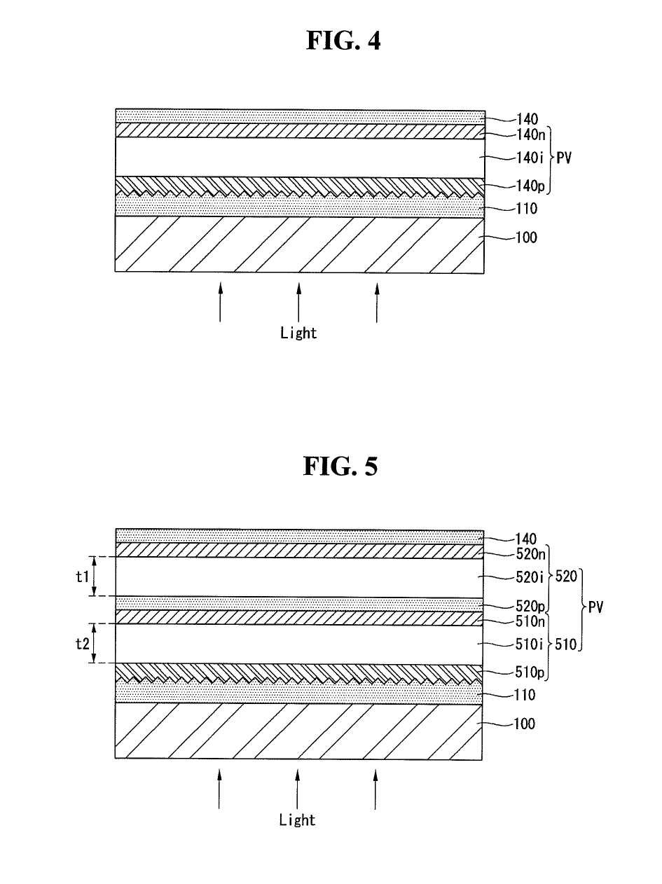

The first electrode 110, the photoelectric conversion unit PV, and the second electrode 140 are described in detail below with reference to FIGS. 4 to 6.

As shown in FIGS. 1 and 2, the substrate 100 includes a first region S1 and a second region S2. The first region S1 is positioned at an edge, such as a peripheral edge, of the substrate 100, and a dummy cell, which does not affect the generation of electric power (i.e., which does not generate electric power in the thin film solar cell 10), is not disposed in the first region S1. The second region S2 corresponds to a region that remains when the first region S1 is excluded from the substrate 100, and the plurality of effective cells UC are disposed in the second region S2. The plurality of effective cells UC disposed in the second region S2 do not include the dummy cell, which does not affect (or contribute to) the generation of electric power.

Since only the plurality of effective cells UC affecting (or contributing to) the generation of electric power are disposed in the second region S2, the second region S2 may be referred to as an effective region. Since the plurality of effective cells UC affecting (or contributing to) the generation of electric power are not disposed in the first region S1, the first region S1 may be referred to as an ineffective region.

In other words, in the thin film solar cell 10 according to the embodiment of the invention, the plurality of effective cells UC are not disposed in the first region S1. Further, only the plurality of effective cells UC affecting (or contributing to) the generation of electric power are disposed in the second region S2, and the dummy cell is not disposed in the second region S2. Therefore, it is possible to increase the number of effective cells UC in the effective region.

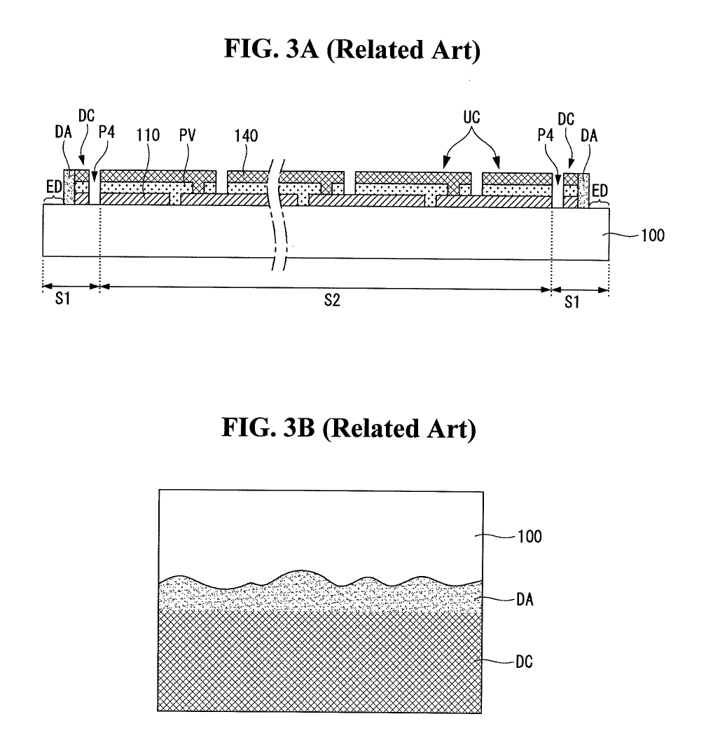

This is described in detail as compared to a solar cell shown in FIGS. 3A and 3B, in which a dummy cell is disposed in a first region.

FIG. 3A illustrates an example structure of a related art solar cell in which a dummy cell is formed in a first region. FIG. 3B illustrates a dummy cell and a damaged region as viewed from the top of the dummy cell of the related art solar cell.

As shown in FIG. 3A, a related art solar cell including a dummy cell is generally formed by forming a first electrode 110, a photoelectric conversion unit PV, and a second electrode 140 on the entire surface of a substrate 100 and then performing an edge deletion process for removing portions ED of the first electrode 110, the photoelectric conversion unit PV, and the second electrode 140 formed at an end of the substrate 100 using a sandblast method or a laser in a final process.

As shown in FIGS. 3A and 3B, after the edge deletion process is performed, a width of an interface between an end of a cell subjected to the edge deletion process and an exposed surface of the substrate 100 is approximately 10 μm to 50 μm, and a region DA damaged by the sandblast method or the laser is generated at the interface. The damaged region DA is generated because the sandblast method or the laser used in the edge deletion process outputs enough power to damage the cell.

As discussed above, one reason to use the laser generating the relatively high output power in the edge deletion process is to reduce process time because a relatively large-sized damaged region of the cell on the substrate 100 has to be removed.

The damaged region DA is generated by a structure of the cell including the first electrode 110, the photoelectric conversion unit PV, and the second electrode 140 being damaged by the sandblast method or the laser. Therefore, electric current generated in the cell is leaked in the damaged region DA.

Accordingly, after the edge deletion process is performed, an edge isolation process is performed so as to reduce the generation of the leaked electric current. In the edge isolation process, the same portions P4 of the first electrode 110, the photoelectric conversion unit PV, and the second electrode 140 over the substrate 100 are removed using the laser in an inner direction (or to the inside) of the edge deletion portion ED formed during the edge deletion process, thereby exposing a portion of the substrate 100.

After the edge isolation process is performed, a dummy cell DC shown in FIG. 3A is generated. The dummy cell DC may be insulated from effective cells UC and may prevent the electric current generated in the effective cells UC from being leaked.

In the above-described solar cell including the dummy cell DC, the plurality of effective cells UC affecting (or contributing to) the generation of electric power are yet formed in the second region S2 in the same manner as the embodiments of the invention, and the dummy cell DC, which does not affect (or contribute to) the generation of electric power, is formed in the first region S1.

The first electrode 110, the photoelectric conversion unit PV, and the second electrode 140 are also formed in the dummy cell DC. However, because the dummy cell DC is electrically isolated from the effective cells UC by the portion P4 formed in the edge isolation process, the dummy cell DC does not affect (or contribute to) the generation of electric power of the solar cell.

As discussed above, when the dummy cell DC is formed in the first region S1, the width of the first region S1 increases by a region occupied by the dummy cell DC, and the width of the second region S2 relatively decreases because of the increased first region S1. Hence, the number of effective cells UC formed in the second region S2 relatively decreases. As a result, photoelectric efficiency of the solar cell is reduced.

On the other hand, in the thin film solar cell according to the embodiments of the invention, the damaged region DA is not generated during the edge deletion process, and the dummy cell does not exist in all of the regions of the substrate 100, i.e. in both the first and second regions S1 and S2 (i.e., the ineffective region and the effective region). Thus, the photoelectric efficiency of the thin film solar cell may increase.

A width of the first region S1 of the substrate 100 may be approximately 5 mm to 20 mm.

After the solar cell shown in FIG. 2 is formed, a solar cell module may be surrounded by a predetermined material, for example, ethylene vinyl acetate (EVA). A frame may be formed on the side of the solar cell module surrounded by EVA. The frame overlaps the incident surface of the substrate 100 by the width of the first region S1. In other words, because the frame and the substrate 100 may overlap each other by the width of the first region S1, light incident on the first region S1 among light incident on the incident surface of the substrate 100 may be shielded.

Accordingly, when the width of the first region S1 corresponding to the overlap portion between the frame and the substrate 100 is equal to or greater than 5 mm, the substrate 100 may be stably supported by the frame.

Further, when the size of the overlap portion between the frame and the substrate 100 is excessively large, the efficiency of the solar cell module may be reduced. Therefore, when the width of the first region S1 is equal to or less than 20 mm, a large amount of light may be incident on the incident surface of the substrate 100. Further, the size of the second region S2 in which the effective cells UC are formed may be sufficiently secured, and the efficiency of the solar cell module may be improved.

FIGS. 4 to 6 specifically illustrate various cells that may be included in the thin film solar cells shown in FIG. 1.

As shown in FIG. 4, the thin film solar cell 10 may have a p-i-n structure in embodiments of the invention.

FIG. 4 illustrates the photoelectric conversion unit PV having the p-i-n structure based on the incident surface of the substrate 100. Additionally, the photoelectric conversion unit PV may have an n-i-p structure based on the incident surface of the substrate 100 in other embodiments of the invention. In the following description, the photoelectric conversion unit PV having the p-i-n structure based on the incident surface of the substrate 100 is taken as an example for the sake of brevity.

As shown in FIG. 4, the thin film solar cell 10 may includes the substrate 100, the first electrode 110 positioned on the substrate 100, the second electrode 140, and the photoelectric conversion unit PV having the p-i-n structure.

The substrate 100 may provide a space for other functional layers. The substrate 100 may be formed of a substantially transparent material, for example, glass or plastic, so that light incident on the substrate 100 efficiently reaches the photoelectric conversion unit PV.

The first electrode 110 positioned on the substrate 100 may contain a substantially transparent material with electrical conductivity so as to increase a transmittance of incident light. More specifically, the first electrode 110 may be formed of a material having high light transmittance and high electrical conductivity, so as to transmit most of incident light and pass through electric current. For example, the first electrode 110 may be formed of at least one selected from the group consisting of indium tin oxide (ITO), tin-based oxide (for example, SnO₂), AgO, ZnO—Ga₂O₃ (or ZnO—Al₂O₃), fluorine tin oxide (FTO), and a combination thereof. A specific resistance of the first electrode 110 may be about 10⁻² Ω·cm to 10⁻¹¹ Ω·cm.

The first electrode 110 may be electrically connected to the photoelectric conversion unit PV. Hence, the first electrode 110 may collect carriers (for example, holes) produced by the incident light and may output the carriers.

A plurality of uneven portions may be formed on an upper surface of the first electrode 110, and the uneven portions may have a non-uniform pyramid structure. In other words, the first electrode 110 may have a textured surface. As discussed above, when the surface of the first electrode 110 is textured, the first electrode 110 may reduce a reflectance of incident light and increase an absorptance of light. Hence, the efficiency of the thin film solar cell 10 may be improved.

Although FIG. 4 shows only the uneven portions of the first electrode 110, the photoelectric conversion unit PV may have a plurality of uneven portions among various layers and/or surfaces. In the embodiment of the invention, for example, only the uneven portions of the first electrode 110 are described below for the sake of brevity.

The second electrode 140 may be formed of metal with high electrical conductivity so as to increase a recovery efficiency of electric power produced by the photoelectric conversion unit PV. The second electrode 140 electrically connected to the photoelectric conversion unit PV may collect carriers (for example, electrons) produced by incident light and may output the carriers.

The photoelectric conversion unit PV is positioned between the first electrode 110 and the second electrode 140 and produces the electric power using light coming from the outside.

The photoelectric conversion unit PV may have the p-i-n structure including a p-type semiconductor layer 140p, an intrinsic (called i-type) semiconductor layer 140i, and an n-type semiconductor layer 140n that are sequentially formed on the incident surface of the substrate 100 in the order named. Other layers may be included or present in the photoelectric conversion unit PV.

The p-type semiconductor layer 140p may be formed using a gas obtained by adding impurities of a group III element, such as boron (B), gallium (Ga), and indium (In), to a raw gas containing silicon (Si).

The i-type semiconductor layer 140i may prevent or reduce a recombination of carriers and may absorb light. The i-type semiconductor layer 140i may absorb incident light to produce carriers such as electrons and holes. The i-type semiconductor layer 140i may be a semiconductor of various kinds, and may be one containing contain microcrystalline silicon (mc-Si), for example, hydrogenated microcrystalline silicon (mc-Si:H). Additionally, the i-type semiconductor layer 140i may contain amorphous silicon (a-Si), for example, hydrogenated amorphous silicon (a-Si:H).

The n-type semiconductor layer 140n may be formed using a gas obtained by adding impurities of a group V element, such as phosphorus (P), arsenic (As), and antimony (Sb), to a raw gas containing silicon (Si).

The photoelectric conversion unit PV may be formed using a chemical vapor deposition (CVD) method, such as a plasma enhanced CVD (PECVD) method.

In the photoelectric conversion unit PV, the p-type semiconductor layer 140p and the n-type semiconductor layer 140n may form a p-n junction with the i-type semiconductor layer 140i interposed therebetween. In other words, the i-type semiconductor layer 140i may be positioned between the p-type semiconductor layer 140p (i.e., a p-type doped layer) and the n-type semiconductor layer 140n (i.e., an n-type doped layer).

In such a structure of the thin film solar cell 10, when light is incident on the p-type semiconductor layer 140p, a depletion region is formed inside the i-type semiconductor layer 140i because of the p-type semiconductor layer 140p and the n-type semiconductor layer 140n each having a relatively high doping concentration, thereby generating an electric field. Electrons and holes produced in the i-type semiconductor layer 140i corresponding to a light absorbing layer are separated from each other by a contact potential difference through a photovoltaic effect and move in different directions. For example, the holes may move to the first electrode 110 through the p-type semiconductor layer 140p, and the electrons may move to the second electrode 140 through the n-type semiconductor layer 140n. Hence, the electric power may be produced when layers 140p and 140n are respectively connected by external wires, for example.

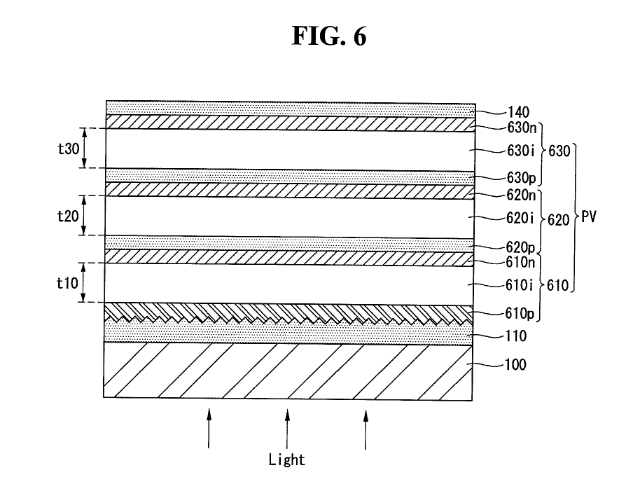

Alternatively, as shown in FIG. 5, the thin film solar cell 10 according the embodiment of the invention may have a double junction structure or a p-i-n/p-i-n structure. In the following explanations, structural elements having the same functions and structures as those discussed previously are designated by the same reference numerals, and the explanations therefore will not be repeated unless they are necessary.

As shown in FIG. 5, the photoelectric conversion unit PV of the thin film solar cell 10 may include a first photoelectric conversion unit 510 and a second photoelectric conversion unit 520. More specifically, a first p-type semiconductor layer 510p, a first i-type semiconductor layer 510i, a first n-type semiconductor layer 510n, a second p-type semiconductor layer 520p, a second i-type semiconductor layer 520i, and a second n-type semiconductor layer 520n may be sequentially stacked on the incident surface of the substrate 100 in the order named. Other layers may be included or present in the photoelectric conversion unit PV.

The first i-type semiconductor layer 510i may mainly absorb light of a short wavelength band to produce electrons and holes. The second i-type semiconductor layer 520i may mainly absorb light of a long wavelength band to produce electrons and holes.

As discussed above, because the double junction thin solar cell 10 absorbs light of the short wavelength band and light of the long wavelength band to produce carriers, the efficiency of the double junction thin film solar cell 10 can be improved.

A thickness t1 of the second i-type semiconductor layer 520i may be greater than a thickness t2 of the first i-type semiconductor layer 510i, so as to sufficiently absorb light of the long wavelength band.

The first i-type semiconductor layer 510i of the first photoelectric conversion unit 510 and the second i-type semiconductor layer 520i of the second photoelectric conversion unit 520 may contain amorphous silicon. Alternatively, the first i-type semiconductor layer 510i of the first photoelectric conversion unit 510 may contain amorphous silicon, and the second i-type semiconductor layer 520i of the second photoelectric conversion unit 520 may contain microcrystalline silicon.

In the double junction thin film solar cell 10 shown in FIG. 5, the second i-type semiconductor layer 520i of the second photoelectric conversion unit 520 may be doped with germanium (Ge) as impurities. Because germanium (Ge) may reduce a band gap of the second i-type semiconductor layer 520i, an absorptance of the second i-type semiconductor layer 520i with respect to light of the long wavelength band may increase. Hence, the efficiency of the double junction thin film solar cell 10 may be improved.

In other words, in the double junction thin film solar cell 10, the first i-type semiconductor layer 510i may absorb light of the short wavelength band to provide the photoelectric effect, and the second i-type semiconductor layer 520i may absorb light of the long wavelength band to provide the photoelectric effect. Further, because the band gap of the second i-type semiconductor layer 520i doped with Ge may be reduced, the second i-type semiconductor layer 520i may absorb a large amount of light of the long wavelength band. As a result, the efficiency of the double junction thin film solar cell 10 may be improved.

The PECVD method may be used to dope the second i-type semiconductor layer 520i with Ge. In the PECVD method, a very high frequency (VHF), a high frequency (HF), or a radio frequency (RF) may be applied to a chamber filled with Ge gas.

In the embodiment of the invention, an amount of Ge contained in the second i-type semiconductor layer 520i may be about 3 to 20 atom %. When the amount of Ge is within the above range, the band gap of the second i-type semiconductor layer 520i may be sufficiently reduced. Hence, an absorptance of the second i-type semiconductor layer 520i with respect to light of the long wavelength band may increase.

Even in this instance, the first i-type semiconductor layer 510i may mainly absorb light of the short wavelength band to produce electrons and holes. The second i-type semiconductor layer 520i may mainly absorb light of the long wavelength band to produce electrons and holes.

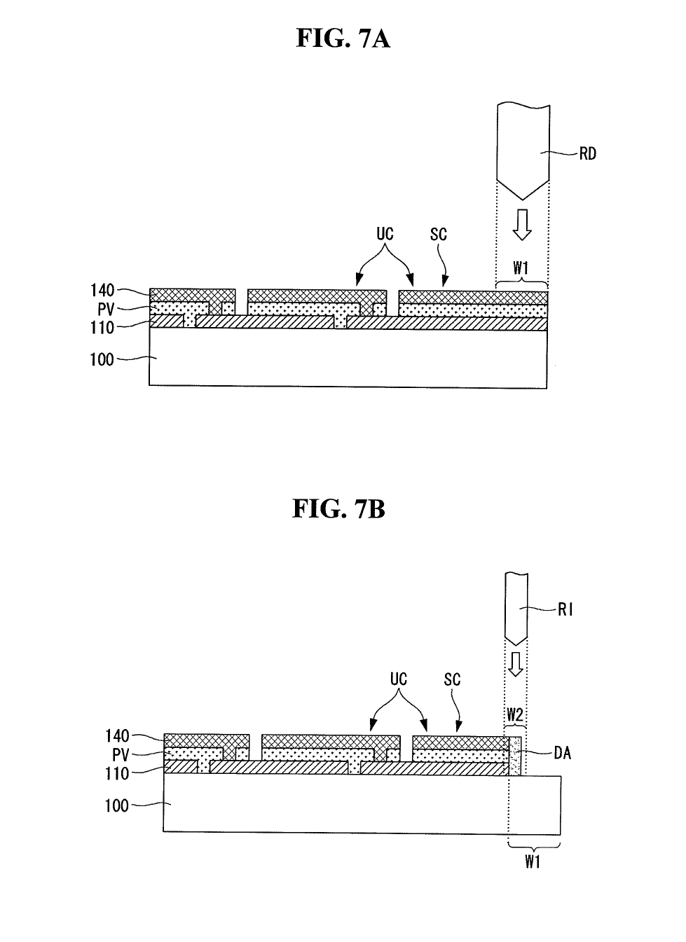

Alternatively, as shown in FIG. 6, the thin film solar cell 10 according the embodiment of the invention may have a triple junction structure or a p-i-n/p-i-n/p-i-n structure. In the following explanations, structural elements having the same functions and structures as those discussed previously are designated by the same reference numerals, and the explanations therefore will not be repeated unless they are necessary.

As shown in FIG. 6, the photoelectric conversion unit PV of the triple junction thin film solar cell 10 may include a first photoelectric conversion unit 610, a second photoelectric conversion unit 620, and a third photoelectric conversion unit 630 that are sequentially positioned on the incident surface of the substrate 100 in the order named. Other layers may be included or present in the first, second and/or third photoelectric conversion units or therebetween

Each of the first photoelectric conversion unit 610, the second photoelectric conversion unit 620, and the third photoelectric conversion unit 630 may have the p-i-n structure. A first p-type semiconductor layer 610p, a first i-type semiconductor layer 610i, a first n-type semiconductor layer 610n, a second p-type semiconductor layer 620p, a second i-type semiconductor layer 620i, a second n-type semiconductor layer 620n, a third p-type semiconductor layer 630p, a third i-type semiconductor layer 630i, and a third n-type semiconductor layer 630n may be sequentially positioned on the substrate 100 in the order named. Other layers may be included or present in the first, second, and/or third photoelectric conversion units or therebetween

The first i-type semiconductor layer 610i, the second i-type semiconductor layer 620i, and the third i-type semiconductor layer 630i may be variously implemented.

As a first example, the first i-type semiconductor layer 610i and the second i-type semiconductor layer 620i may contain amorphous silicon (a-Si), and the third i-type semiconductor layer 630i may contain microcrystalline silicon (mc-Si). A band gap of the second i-type semiconductor layer 620i may be reduced by doping the second i-type semiconductor layer 620i with Ge.

Alternatively, as a second example, the first i-type semiconductor layer 610i may contain amorphous silicon (a-Si), and the second i-type semiconductor layer 620i and the third i-type semiconductor layer 630i may contain microcrystalline silicon (mc-Si). A band gap of the third i-type semiconductor layer 630i may be reduced by doping the third i-type semiconductor layer 630i with Ge.

The first photoelectric conversion unit 610 may absorb light of a short wavelength band, thereby producing electric power. The second photoelectric conversion unit 620 may absorb light of a middle wavelength band between a short wavelength band and a long wavelength band, thereby producing electric power. The third photoelectric conversion unit 630 may absorb light of a long wavelength band, thereby producing electric power.

A thickness t30 of the third i-type semiconductor layer 630i may be greater than a thickness t20 of the second i-type semiconductor layer 620i, and the thickness t20 of the second i-type semiconductor layer 620i may be greater than a thickness t10 of the first i-type semiconductor layer 610i.

Because the triple junction thin film solar cell 10 shown in FIG. 6 may absorb light of a wider band, the production efficiency of the electric power of the triple junction thin film solar cell 10 may be improved.

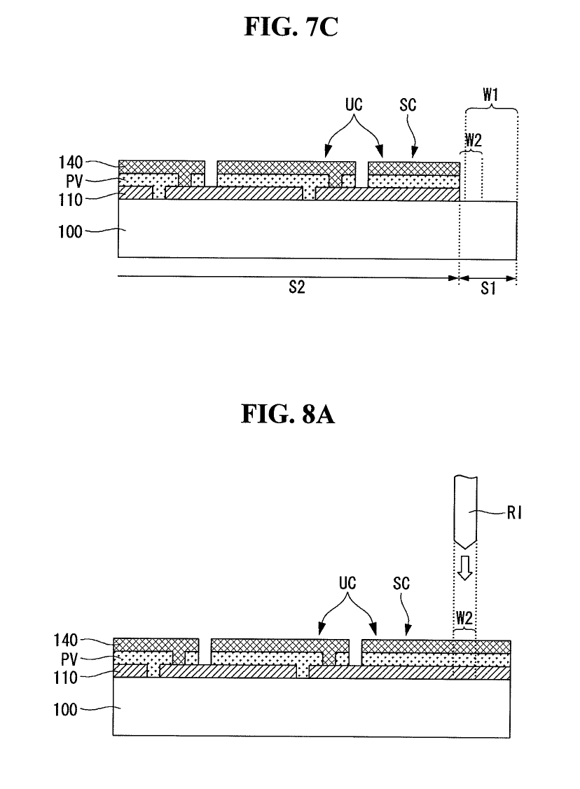

FIGS. 7A to 7C illustrate a method of manufacturing the thin film solar cell according to the example embodiment of the invention.

First, as shown in FIG. 7A, a plurality of cells UC, each of which includes a first electrode 110 positioned on a substrate 100, a second electrode 140 positioned on the first electrode 110, and a photoelectric conversion unit PV that is positioned between the first electrode 110 and the second electrode 140 and converts light incident on an incident surface of the substrate 100 into electricity, are formed.

Next, an edge deletion process is performed, thereby removing the same first portion (or respective first portions) W1 of a first electrode 110, a second electrode 140, and a photoelectric conversion unit PV included in an outermost cell SC positioned at the outermost side of the substrate 100 among the plurality of cells. In the edge deletion process, a first laser RD is irradiated to the same first portion (or respective first portions) W1 of the first electrode 110, the second electrode 140, and the photoelectric conversion unit PV over the substrate 100 and formed at an end of the substrate 100.

A width of the first portion (or respective first portions) W1, to which the first laser RD is irradiated, may be approximately 5 mm to 15 mm extending from the end of the substrate 100 to the inside of the substrate 100. The reason to limit the width of the first portion (or respective first portions) W1 is substantially the same as the reason to limit the width of the first region S1 of the substrate 100 illustrated in FIG. 2. This is because the first region S1 of the substrate 100 is substantially determined by the width of the first portion (or respective first portions) W1.

Accordingly, when the width of the first portion (or respective first portions) W1 is approximately 5 mm to 15 mm, the substrate 100 may be stably supported by the frame, and also a large amount of light may be incident on the incident surface of the substrate 100.

An output power of the first laser RD used to remove the first portions (or respective first portions) W1 of the edge deletion process may be greater than an output power of a second laser RI used in a subsequent edge isolation process. This difference is to reduce the process time because the size of the first portion (or respective first portions) W1 removed in the edge deletion process is greater than the size of a second portion (or respective second portions) W2 removed in the edge isolation process.

As shown in FIG. 7B, after the same first portion (or respective first portions) W1 of the first electrode 110, the second electrode 140, and the photoelectric conversion unit PV formed at the end of the substrate 100 is removed using the first laser RD, a damaged region DA is generated at an interface between the end of the outermost cell SC subjected to the edge deletion process and the exposed surface of the substrate 100. The damaged region DA is generated because the first laser RD with the relatively high output power is used so as to reduce the process time in the edge deletion process.

The edge isolation process is then performed so as to remove the damaged region DA of the outermost cell SC, thereby removing the same second portion (or respective second portions) W2 of the first electrode 110, the second electrode 140, and the photoelectric conversion unit PV of the outermost cell SC over the substrate 110. Accordingly, in this embodiment of the invention, the first laser RD is first used to remove most the of the material from the first portions (or respective first portions) W1, then the second laser RI is used to remove any remaining material, such as the damaged region in the second portion (or respective second portions) W2.

The edge isolation process is performed, so that at least a portion of the second portion (or respective second portions) W2 overlaps the first portion (or respective first portions) W1 of the edge deletion process. Hence, the damaged region DA generated at the interface between the end of the outermost cell SC subjected to the edge deletion process and the exposes surface of the substrate 100 is removed. As a result, as shown in FIG. 7C, the dummy cell is not formed in the first region S1, and only the plurality of cells UC are formed in the second region S2, of the substrate 100.

The edge isolation process for removing the second portion (or respective second portions) W2 is performed on an interface between the outermost cell SC and the damaged region DA. Hence, the second portion (or respective second portions) W2 is removed, and the damaged region DA formed at the end of the outermost cell SC is removed.

FIG. 7B illustrates the second portion (or respective second portions) W2 having the width greater than the width of the damaged region DA. Additionally, the width of the second portion (or respective second portions) W2 may be less than the width of the damaged region DA. Even in this instance, the edge isolation process for removing the second portion (or respective second portions) W2 may be performed on the interface between the outermost cell SC and the damaged region DA. However, a portion of the damaged region DA may remain at a location spaced apart from the outermost cell SC. Because the remaining damaged region DA is spaced apart from the outermost cell SC, the electric current is not leaked. As a result, the efficiency of the thin film solar cell is not reduced.

In the embodiment of the invention, because the width of the second portion (or respective second portions) W2 is less than the width of the first portion (or respective first portions) W1, a reduction in the size of the second region S2 resulting from the edge isolation process may be prevented or reduced.

For example, when the width of the second portion (or respective second portions) W2 is approximately 10 μm to 100 μm, a reduction in the width of the second region S2 resulting from the edge isolation process may be prevented or reduced.

In the embodiment of the invention, the output power of the second laser RI used to remove the second portion (or respective second portions) W2 in the edge isolation process may be less than the output power of the first laser RD used to remove the first portion (or respective first portions) W1 of the edge deletion process. Hence, after the edge isolation process is performed, the damaged region DA may not be generated at the interface between the end of the outermost cell SC and the exposed surface of the substrate 100. Even if the damaged region DA is generated in the edge deletion process, the damaged region DA may be removed.

As shown in FIG. 7C, in the thin film solar cell thus manufactured, the first region S1 is formed by the first portion (or respective first portions) W1 of the edge deletion process and the second portion (or respective second portions) W2 of the edge isolation process.

In the method of manufacturing the thin film solar cell according to the embodiment of the invention, the first portion (or respective first portions) W1 and the second portion (or respective second portions) W2 partially overlap each other, thereby forming the first region S1, that does not affect (or contribute to) the generation of electric power of thin film solar cell. The number of effective cells UC disposed in the second region S2 may increase by minimizing the width of the first region S1. Hence, the photoelectric conversion efficiency of the thin film solar cell may be improved. That is, given a fixed area of the substrate 100, the second region S2 of the embodiment of the invention is relatively greater than the second region of a related art solar cell based on having relatively smaller first region S1 than that of the related art solar cell.

So far, in the method of manufacturing the thin film solar cell according to the embodiment of the invention, after the edge deletion process is performed, the edge isolation process is performed. Additionally, after the edge isolation process is performed, the edge deletion process may be performed.

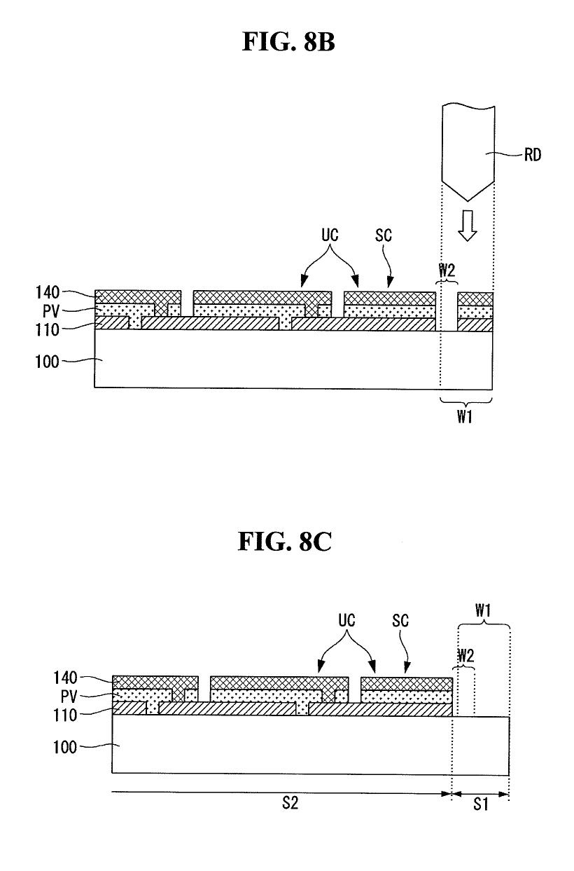

FIGS. 8A to 8C illustrate another method of manufacturing the thin film solar cell according to the example embodiment of the invention. More specifically, FIGS. 8A to 8C illustrate the method of manufacturing the thin film solar cell, in which the edge isolation process is followed by the edge deletion process.

As shown in FIG. 8A, a first electrode 110 is formed on a substrate 100, a photoelectric conversion unit PV is formed on the first electrode 110, and a second electrode 140 is formed on the photoelectric conversion unit PV. Then, an edge isolation process is performed.

In the edge isolation process, a second laser RI with a relatively low output power is irradiated to the same second portion (or respective second portions) W2 of the first electrode 110, the second electrode 140, and the photoelectric conversion unit PV over the substrate 100, thereby removing the second portion (or respective second portions) W2.

As shown in FIG. 8B, after the edge isolation process is performed, the thin film solar cell, in which the same second portion (or respective second portions) W2 of the first electrode 110, the second electrode 140, and the photoelectric conversion unit PV over the substrate is removed, is formed.

The width of the second portion (or respective second portions) W2 may be approximately 10 μm to 100 μm as discussed above with reference to FIG. 7B.

When the edge isolation process is followed by the edge deletion process, a location of the second portion (or respective second portions) W2 may be determined in consideration of the width of the first portion (or respective first portions) W1 of the edge deletion process.

As shown in FIG. 8B, after the second portion (or respective second portions) W2 is removed through the edge isolation process, the edge deletion process is performed using a first laser RD with relatively high output power to remove the same first portion (or respective first portions) W1 of the first electrode 110, the second electrode 140, and the photoelectric conversion unit PV over the substrate 100 partially overlapping the second portion (or respective second portions) W2. Hence, the solar cell shown in FIG. 8C may be formed.

Because the edge deletion process is performed in a state where the second portion (or respective second portions) W2 is removed through the edge isolation process, a damaged region shown in FIG. 7B is not generated in the thin film solar cell.

As discussed above, in the method of manufacturing the thin film solar cell according to the example embodiment of the invention, because the width of the first region S1 is minimized, the number of effective cells disposed in the second region S2 may increase. Hence, the photoelectric conversion efficiency of the thin film solar cell may be improved given a fixed area of the substrate 100.

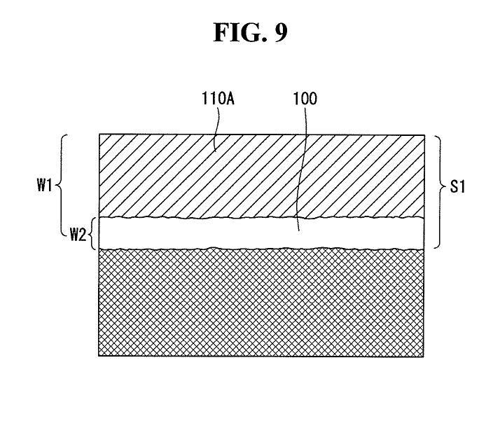

FIG. 9 illustrates an example structure of a solar cell in which a dummy cell is not formed in a first region as viewed from the top according to an example embodiment of the invention.

In FIG. 9, the first region S1 is formed by the first portion (or respective first portions) W1 of the edge deletion process and the second portion (or respective second portions) W2 of the edge isolation process, whereby the first portion (or respective first portions) W1 and the second portion (or respective second portions) W2 partially overlap each other, and forming the first region S1 does not adversely affect (or contribute to) the generation of electric power of thin film solar cell. In embodiments of the invention, the second portion, (or respective second portions) W2 that is subjected to the edge isolation process is clean so that the surface of the substrate 100 is exposed. On the other hand, the first portion (or respective first portions) W1 that does not overlap the second portion (or respective second portions) W2 may have residual material of the first electrode 110 on the surface of the substrate 100. Accordingly, the surface of the substrate 100 may not be completely exposed at portions of the first portion (or respective first portions) W1. In this instance, a portion 110A of the first electrode 110 may be present on the surface of the substrate. In embodiments of the invention, the first portion (or respective first portions) W1 may include a mix of exposed surface of the substrate 110 and remaining portion 110A of the first electrode 110.

In various embodiments of the invention, the one or more photoelectric conversion units of the thin film solar cell may be formed of any semiconductor material. Accordingly, materials for the one or more photoelectric conversion units may include Cadmium telluride (CdTe), Copper indium gallium selenide (CIGS) and/or other materials, including other thin film solar cell materials.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a thin film solar cell comprising:
forming a plurality of cells, each cell including a first electrode positioned on a substrate, a second electrode positioned on the first electrode, and a photoelectric conversion unit that is positioned between the first electrode and the second electrode and is configured to generate electricity from light incident on the substrate;
performing an edge deletion process to remove respective first portions of a first electrode, a second electrode, and a photoelectric conversion unit included in an outermost cell positioned at an end of the substrate among the plurality of cells; and
performing an edge isolation process to remove respective second portions of the first electrode, the second electrode, and the photoelectric conversion unit included in the outermost cell,
wherein at least a portion of the second portions of the edge isolation process overlaps the first portions of the edge deletion process.

2. The method of claim 1, wherein a width of the second portions is less than a width of the first portions.

3. The method of claim 1, wherein a width of the first portions is approximately 5 mm to 15 mm extending from the end of the substrate to an inside of the substrate.

4. The method of claim 1, wherein a width of the second portions is approximately 10 μm to 100 μm.

5. The method of claim 1, wherein an output power of a first laser used to remove the first portions in the edge deletion process is greater than an output power of a second laser used to remove the second portions in the edge isolation process.

6. The method of claim 1, wherein after the edge deletion process is performed, the edge isolation process is performed.

7. The method of claim 6, wherein the edge isolation process for removing the second portions is performed on an interface between the outermost cell and a damaged region of the first electrode, the second electrode, and the photoelectric conversion unit included in the outermost cell resulting from the edge deletion process.

8. The method of claim 6, wherein the edge isolation process for removing the second portions is performed to remove a damaged region of the first electrode, the second electrode, and the photoelectric conversion unit included in the outermost cell resulting from the edge deletion process.

9. The method of claim 1, wherein after the edge isolation process is performed, the edge deletion process is performed.

10. A thin film solar cell comprising:
a substrate; and
a plurality of cells, each cell including a first electrode positioned on the substrate, a second electrode positioned on the first electrode, and a photoelectric conversion unit that is positioned between the first electrode and the second electrode and is configured to generate electricity from light incident on the substrate,
wherein no damaged region exits in a first electrode, a second electrode, and a photoelectric conversion unit included in an outermost cell positioned at an end of the substrate among the plurality of cells.

11. The thin film solar cell of claim 10, wherein the substrate includes a first region and a second region, and
a dummy cell, which does not affect generation of electricity, is not disposed in the first region, and the plurality of cells are disposed in the second region.

12. The thin film solar cell of claim 10, wherein the first region is positioned at an edge of the substrate.

13. The thin film solar cell of claim 10, wherein a width of the first region is approximately 5 mm to 20 mm.

14. The thin film solar cell of claim 10, wherein the photoelectric conversion unit has at least one p-i-n structure including a p-type semiconductor layer, an intrinsic semiconductor layer, and an n-type semiconductor layer.

15. The thin film solar cell of claim 14, wherein the intrinsic semiconductor layer of the photoelectric conversion unit contains germanium (Ge).

16. The thin film solar cell of claim 14, wherein the intrinsic semiconductor layer of the photoelectric conversion unit contains at least one of amorphous silicon and microcrystalline silicon.

17. A thin film solar cell comprising:
a substrate; and
a plurality of cells, each cell including a first electrode positioned on the substrate, a second electrode positioned on the first electrode, and a photoelectric conversion unit that is positioned between the first electrode and the second electrode and is configured to generate electricity from light incident on the substrate,
wherein the substrate includes a first exposed portion at a peripheral edge of the substrate, an outermost cell positioned at an end of the substrate among the plurality of cells include a second removed portion exposing the substrate, and the first exposed portion and the second exposed portion partially overlaps.

18. The thin film solar cell of claim 17, wherein the first portion is formed during an edge deletion process and the second portion is formed during an edge isolation process.

19. The thin film solar cell of claim 17, wherein a width of the first and the second portions are approximately 5 mm to 20 mm.

20. The thin film solar cell of claim 17, wherein the first exposed portion exposes a portion of the first electrode.
